(19) United States
(12) Patent Application Publication
(10) Pub. No.: US 2010/0226651 A1
(43) Pub. Date: Sep. 9, 2010

(54) THREE-WAY OPTICAL DEVICE

(75) Inventors: Tuan Yu Hung, Hsinchu County (TW); Chang You Li, Hsinchu County (TW); Wen Chih Hsieh, Hsinchu County (TW); I Hsiu Chen, Hsinchu County (TW); Ling Ying Chiang, Hsinchu County (TW)

Correspondence Address: MORRIS MANNING MARTIN LLP, 3343 PEACHTREE ROAD, NE, 1600 ATLANTA FINANCIAL CENTER, ATLANTA, GA, 30326, US

(73) Assignee: APAC OPTO ELECTRONICS INC., Hsinchu County (TW)

(21) Appl. No.: 12/634,501

(22) Filed: Dec. 9, 2009

(30) Foreign Application Priority Data
Mar. 4, 2009 (TW) 098107025

(51) Int. Cl. H04J 14/02; H01L 31/0232; H01L 31/09

(52) U.S. Cl. 398/79; 250/226

(57) ABSTRACT

A three-way optical device includes a case, a sleeve connected to one of openings of the case, photoelectric elements disposed in one of the openings, and optical filters. Each photoelectric element is associated with an optical signal. Each optical filter is located in the case, corresponding to at least two photoelectric elements, and each optical filter is disposed on an optical path of optical signals associated with the at least two corresponding photoelectric elements. Each optical filter enables the optical signal associated with at least one photoelectric element to penetrate and reflects optical signals associated with the remaining corresponding photoelectric elements, in which the optical signals reflected by the optical filter and penetrating the same optical filter have different wavelengths. The optical signals having different wavelengths associated with the corresponding photoelectric elements are transmitted in a manner of penetrating the optical filters or being reflected by the optical filters.

### CROSS-REFERENCE TO RELATED APPLICATIONS

This non-provisional application claims priority under 35 U.S.C. §119(a) on Patent Application No(s). 098107025 filed in Taiwan, R.O.C. on Mar. 4, 2009, the entire contents of which are hereby incorporated by reference.

### BACKGROUND OF THE INVENTION

1. Field of the Invention

The present invention relates to a wavelength division multiplexing (WDM) device of the optical fiber communication, and more particularly to a three-way optical device.

2. Related Art

Thanks to the advantages of high transmission speed, low noise, small weight, high security, and the like, optical fibers have become an indispensable transmission medium in the current communication network. With the development trend of the whole communication techniques and applications all over the world, the applications of the techniques associated with optical fibers have become indispensable transmission media for the optical fiber communication network, data transmission, and cable television, etc., and have the infinite market potential in the future, such that each advanced country in the world competes with one another for the techniques associated with the optical fibers. However, in the fundamental constructions of the optical fiber communication network, optical fiber passive components have a high technical level, high product-added value, and low capital investment, and act as critical components for the optical fiber network, so as to be focused by the manufacturers from home and aboard.

The optical fiber elements may be divided into active elements and passive elements. The active elements include an optical transceiver module and a photoelectric converter. The passive elements include an optical fiber coupler, an optical fiber attenuator, an optical fiber filter, an optical fiber isolator, an optical fiber polarizer, an optical fiber wave splitter, an optical fiber connector, an optical path switch, an optical fiber collimator, an optical fiber circulator, an optical fiber wavelength multiplexer, an optical fiber grating, an optical fiber amplifier, an optical fiber patch cord, etc.

In order to transmit signals with different wavelengths in a single optical fiber to achieve a broadband effect, a multiplexing function of coupling the signals with different wavelengths in a single optical fiber for transmission, and a de-multiplexing function of splitting the signals with different wavelengths transmitted in a single optical fiber are realized in the conventional optical fiber communication through the WDM technique.

In order to achieve the WDM function, a grating or an optical waveguide is required to couple the signals with different wavelengths in the single optical fiber for transmission or split the signals with different wavelengths transmitted in a single optical fiber. However, the process for manufacturing the grating and the optical waveguide is not easy, and when the optical signals are coupled or split, the loss of signals usually occurs due to a poor coupling efficiency.

### SUMMARY OF THE INVENTION

The present invention is a three-way optical device, such that a loss of optical signals does not easily occur due to a poor coupling efficiency when a grating and an optical waveguide are used to couple or split the optical signals.

The three-way optical device according to the present invention comprises a case, a sleeve, photoelectric elements, and optical filters.

The case has a plurality of openings on surfaces thereof.

One end of the sleeve is connected to one of the plurality of openings.

Each photoelectric element is disposed in one of the plurality of openings and associated with an optical signal.

The optical filters are located in the case. Each optical filter corresponds to at least two photoelectric elements among the plurality of photoelectric elements and is disposed on an optical path of optical signals associated with the at least two corresponding photoelectric elements. Each optical filter enables the optical signal associated with at least one photoelectric element of the at least two corresponding photoelectric elements to penetrate, and reflects the optical signals associated with the remaining photoelectric elements of the at least two corresponding photoelectric elements. The optical signals reflected by the optical filter and that penetrating the same optical filter have different wavelengths.

Each photoelectric element is one of an optical transmitter and an optical receiver. The sleeve comprises a lens. The lens is located on one end of the sleeve connected to the case, and is used to converge optical signals.

The optical transmitter is used to send an optical signal into the case, in which the optical signal sent from the optical transmitter is transmitted to the sleeve via a corresponding optical filter.

The optical receiver is used to receive an optical signal transmitted through the sleeve, in which the optical signal transmitted through the sleeve is transmitted to the optical receiver via a corresponding optical filter.

In the three-way optical device according to the present invention, each optical filter is used to enable the optical signal associated with at least one photoelectric element of the at least two corresponding photoelectric elements to penetrate, and used to reflect the optical signals associated with the remaining photoelectric elements of the at least two corresponding photoelectric elements, in which the optical signals reflected by the optical fiber and that penetrating the same optical filter have different wavelengths.

Therefore, the three-way optical device enables a photoelectric element to transmit an optical signal into the sleeve through penetrating an optical filter, and also enables an optical signal transmitted through the sleeve to be transmitted to a corresponding photoelectric element through penetrating an optical filter. The three-way optical device enables a photoelectric element to reflect an optical signal into the sleeve through an optical filter, and also enables an optical signal transmitted through the sleeve to be reflected to a corresponding photoelectric element through an optical filter. In the three-way optical device, since the optical signals reflected by the optical filter and that penetrating the optical filter have different wavelengths, the optical signals with different wavelengths are transmitted to the sleeve or corresponding photoelectric elements in reflecting and penetrating manners, without the problem of the loss of signals when the grating or the optical waveguide is used to couple the optical signals, thereby achieving the function of multiplexing or de-multiplexing the optical signals.

### BRIEF DESCRIPTION OF THE DRAWINGS

The present invention will become more fully understood from the detailed description given herein below for illustration only, and thus is not limitative of the present invention, and wherein:

FIG. 1 is a schematic view of a three-way optical device according to a first embodiment of the present invention;

FIG. 2 is a schematic view of a three-way optical device according to a second embodiment of the present invention; and

FIG. 3 is a schematic view of a three-way optical device according to a third embodiment of the present invention.

### DETAILED DESCRIPTION OF THE INVENTION

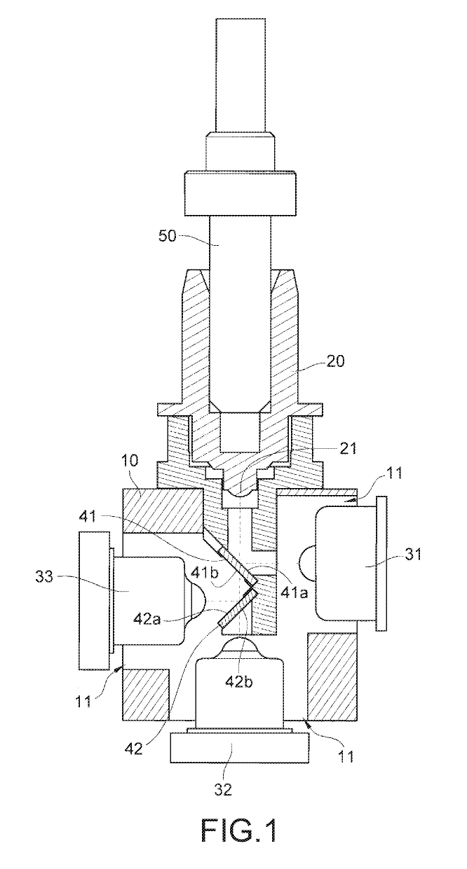

FIG. 1 is a schematic view of a three-way optical device according to a first embodiment of the present invention.

Referring to FIG. 1, in this embodiment, the three-way optical device comprises a case 10, a sleeve 20, a plurality of photoelectric elements, and a plurality of optical filters 41 and 42.

In this embodiment, the photoelectric elements comprise an optical transmitter 31, an optical transmitter 32, and an optical transmitter 33.

For ease of description, in this embodiment, the number of the photoelectric elements is three, but the present invention is not limited thereto, and the number of the photoelectric elements may be one, two, or more than three.

For ease of description, in this embodiment, the number of the optical filters is two, but the present invention is not limited thereto, and the number of the optical filters may be one or more than two.

The case 10 has a plurality of openings 11. The plurality of openings 11 may be respectively opened on different side walls of the case 10.

One end of the sleeve 20 is connected to one of the plurality of openings 11. The sleeve 20 comprises a lens 21. The lens 21 is located on one end of the sleeve 20 connected to the case 10.

The photoelectric elements are respectively disposed in the openings, and each photoelectric element is associated with one optical signal.

Here, the optical transmitter 31 is correspondingly disposed in one of the plurality of openings 11. The optical transmitter 32 is correspondingly disposed in one of the plurality of openings 11. The optical transmitter 33 is correspondingly disposed in one of the plurality of openings 11.

The optical filter 41 is located in the case 10 and is disposed corresponding to the optical transmitter 31. Here, the optical filter 41 has a first surface 41a and a second surface 41b opposite to each other.

The optical transmitter 31 corresponds to the first surface 41a of the optical filter 41, that is, a light exit surface of the optical transmitter 31 faces the first surface 41a of the optical filter 41. In this case, an optical signal sent from the optical transmitter 31 is incident to the first surface 41a of the optical filter 41, and then is reflected through the first surface 41a.

The optical filter 41 may also be disposed corresponding to the optical transmitter 32. Here, the optical transmitter 32 corresponds to the second surface 41b of the optical filter 41, that is, a light exit surface of the optical transmitter 32 faces the second surface 41b of the optical filter 41. In this case, an optical signal sent from the optical transmitter 32 is incident to the second surface 41b of the optical filter 41, penetrates the optical filter 41, and then is sent through the first surface 41a.

The optical filter 42 is located in the case 10 and is disposed corresponding to the optical transmitter 33. Here, the optical filter 42 has a first surface 42a and a second surface 42b opposite to each other.

The optical transmitter 33 corresponds to the first surface 42a of the optical filter 42, that is, a light exit surface of the optical transmitter 33 faces the first surface 42a of the optical filter 42. In this case, an optical signal sent from the optical transmitter 33 is incident to the first surface 42a of the optical filter 42, and then is reflected through the first surface 42a.

The optical filter 42 may also be disposed corresponding to the optical transmitter 32. Here, the optical transmitter 32 corresponds to the second surface 42b of the optical filter 42, that is, a light exit surface of the optical transmitter 32 faces the second surface 42b of the optical filter 42. In this case, an optical signal sent from the optical transmitter 32 is incident to the second surface 42b of the optical filter 42, penetrates the optical filter 42, and then is sent through the first surface 42a.

The first surface 41a of the optical filter 41 is obliquely disposed corresponding to the optical transmitter 31 and the lens 21. Because of an oblique angle of the optical filter 41, the optical signal sent from the optical transmitter 31 is reflected to the lens 21 through the first surface 41a of the optical filter 41. In addition, because of the oblique angle of the optical filter 41, the optical signal sent from the optical transmitter 32 penetrates the optical filter 41.

In other words, an incident angle is formed between an optical axis of the light exit surface of the optical transmitter 31 and a normal line of the first surface 41a of the optical filter 41, and a reflection angle is formed between an optical axis of the lens 21 and the normal line of the first surface 41a of the optical fiber 41, in which the incident angle is equal to or approximates the reflection angle.

The optical filter 41 is correspondingly disposed between the optical transmitter 32 and the lens 21, such that the optical signal sent from the optical transmitter 32 reaches the lens 21 after penetrating the optical filter 41.

The first surface 42a of the optical filter 42 is obliquely disposed corresponding to the optical transmitter 33 and the lens 21. Because of the oblique angle of the optical filter 42, the optical signal sent from the optical transmitter 33 is reflected to the lens 21 through the first surface 42a of the optical filter 42.

An incident angle is formed between an optical axis of the light exit surface of the optical transmitter 33 and a normal line of the first surface 42a of the optical filter 42, and a reflection angle is formed between the optical axis of the lens 21 and the normal line of the first surface 42a of the optical filter 42, in which the incident angle is equal to or approximates the reflection angle.

The optical filter 42 is disposed between the optical transmitter 32 and the lens 21, and the optical filter 42 is disposed between the optical filter 41 and the optical transmitter 32. The optical signal sent from the optical transmitter 32 penetrates the optical filter 42, then penetrates the optical filter 41, and is incident to the lens 21. The optical signal sent from the optical transmitter 33 is reflected by the optical filter 42, is incident to the optical filter 41, penetrates the optical filter 41, and is incident to the lens 21.

The optical transmitter 31, the optical transmitter 32, and the optical transmitter 33 are respectively used to send optical signals into the case 10. The wavelengths of the optical signals sent from the optical transmitter 31, the optical transmitter 32, and the optical transmitter 33 are in different bands.

In other words, each optical filter 41/42 is disposed corresponding to at least two photoelectric elements (that is, optical transmitters 31, 32/32, and 33), and the photoelectric elements (that is, optical transmitters 31, 32/32, and 33) corresponding to each optical filter 41/42 are associated with optical signals having different wavelengths. Each optical filter 41/42 enables the optical signal in one band to penetrate and reflects the optical signal in another band.

In this embodiment, the three-way optical device further comprises a patch cord 50. One end of the patch cord 50 is inserted into the sleeve 20, and the other end is used to accommodate one end of the optical fiber.

The optical filter 41 selectively enables an optical signal in a first band to penetrate and reflects an optical signal in a second band. In this embodiment, the optical filter 41 is used to selectively enable the optical signal in the first band sent from the corresponding optical transmitter 31 to penetrate and reflect the optical signal in the second band sent from the corresponding optical transmitter 32, so as to transmit the optical signal in the first band sent from the corresponding optical transmitter 31 and the optical signal in the second band sent from the corresponding optical transmitter 32 to the sleeve 20. The optical signal in the first band sent from the optical transmitter 31 is reflected to the sleeve 20 by the optical filter 41. The optical signal in the second band sent from the corresponding optical transmitter 32 reaches the sleeve 20 after penetrating the optical filter 41. The first band and the second band are within different band ranges.

The optical filter 42 selectively enables the optical signal in the second band to penetrate and reflects an optical signal in a third band. In this embodiment, the optical filter 42 is used to selectively enable the optical signal in the second band sent from the corresponding optical transmitter 32 to penetrate and reflect the optical signal in the third band sent from the corresponding optical transmitter 33, so as to transmit the optical signal in the second band sent from the corresponding optical transmitter 32 and the optical signal in the third band sent from the corresponding optical transmitter 33 to the sleeve 20. The optical signal in the third band sent from the optical transmitter 33 is reflected to the sleeve 20 by the optical filter 42. The optical signal in the second band sent from the corresponding optical transmitter 32 penetrates the optical filter 42, penetrates the optical filter 41, and then reaches the lens 21. The second band and the third band are within different band ranges.

After the optical signals sent from the optical transmitter 31, the optical transmitter 32, and the optical transmitter 33 selectively penetrate and are reflected by the optical filter 41 and the optical filter 42, the lens 21 is used to converge the optical signals into the sleeve 20.

The optical filter 41 and the optical filter 42 may be respectively installed within the case 10 by assembling jigs, or may be fixed by the structure of the case 10. Definitely, the optical filter 41 and the optical filter 42 may be fixed within the case 10 in an adhering manner, so as to prevent the optical filter 41 and the optical filter 42 from leaving the optical path due to being moved or shaken, thereby avoiding the problems that the optical filter 41 and the optical filter 42 fail to correspond to the optical transmitter 31, the optical transmitter 32, and the optical transmitter 33 and the optical signals sent from the optical transmitter 31, the optical transmitter 32, and the optical transmitter 33 cannot be transmitted to the sleeve 20.

After the optical signals are transmitted to the sleeve 20 through being reflected by and penetrating the optical filter 41 and the optical filter 42, the patch cord 50 is used to transmit the optical signals to the optical fiber.

The optical transmitter 31, the optical transmitter 32, and the optical transmitter 33 may be light emitting diodes (LEDs), laser diodes (LDs), and vertical-cavity surface-emitting lasers (VCSELs), etc.

The optical filter 41 and the optical filter 42 are thin films formed on a transparent substrate in, for example, spreading or coating manner, which allow the optical signals in different bands correspondingly sent from the optical transmitter 31, the optical transmitter 32, and the optical transmitter 33 to be reflected or penetrate.

The wavelength of the optical signal sent from the optical transmitter 31 may be between 800 nm and 900 nm. The wavelength of the optical signal sent from the optical transmitter 32 may be between 1490 nm and 1610 nm. The wavelength of the optical signal sent from the optical transmitter 33 may be between 1310 nm and 1350 nm. Definitely, the optical transmitter 31, the optical transmitter 32, and the optical transmitter 33 may also send optical signals in other bands.

The optical filter 41 reflects the incident light having the wavelength between 800 nm and 900 nm, and enables the incident light having the wavelength between 1310 nm and 1610 nm to penetrate, which definitely also enables the incident light within other band ranges to penetrate or to be reflected. The optical filter 42 reflects the incident light having the wavelength between 1250 nm and 1350 nm, and enables the incident light having the wavelength between 1490 nm and 1610 nm to penetrate, which definitely also enables the incident light within other band ranges to penetrate or to be reflected. The above circumstances are merely an embodiment of the present invention, and the present invention is not limited thereto, and the optical filters (41, 42) may select the bands of the incident lights to penetrate or to be reflected according to the light emitting elements.

In the three-way optical device according to the present invention, the optical signal sent from the corresponding optical transmitter 31 is reflected to the lens 21 by the optical filter 41, then the optical signal is converged into the sleeve 20 by the lens 21, and finally the optical signal is transmitted by the patch cord 50 inserted in the sleeve 20 via the optical fiber connected to the other end of the patch cord 50. In the three-way optical device, by using the characteristics of the optical filter 41 and the optical filter 42, the optical signal sent from the optical transmitter 32 reaches the lens 21 after penetrating the optical filter 41 and the optical filter 42, then the optical signal is converged into the sleeve 20 by the lens 21, and finally the optical signal is transmitted by the patch cord 50 inserted in the sleeve 20 via the optical fiber connected to the other end of the patch cord 50. In the three-way optical device, the optical signal sent from the corresponding optical transmitter 33 is reflected to the optical filter 41 by the optical filter 42, the optical signal reaches the lens 21 after penetrating the optical filter 41, then the optical signal is converged into the sleeve 20 by the lens 21, and finally the optical signal is transmitted by the patch cord 50 inserted in the sleeve 20 via the optical fiber connected to the other end of the patch cord 50.

In the three-way optical device, the optical filter 41 and the optical filter 42 are used to transmit the optical signals with different wavelengths correspondingly sent from the optical transmitter 31, the optical transmitter 32, and the optical transmitter 33 corresponding to different wavelengths to the sleeve 20 in one of reflecting and penetrating manners, and then the optical signals are transmitted via the optical fiber connected to the other end of the sleeve 20. The three-way optical device achieves the functions of multiplexing and de-multiplexing the optical signals, without resulting in the problem of the loss of signals caused by the grating or optical waveguide used when the optical signals are coupled.

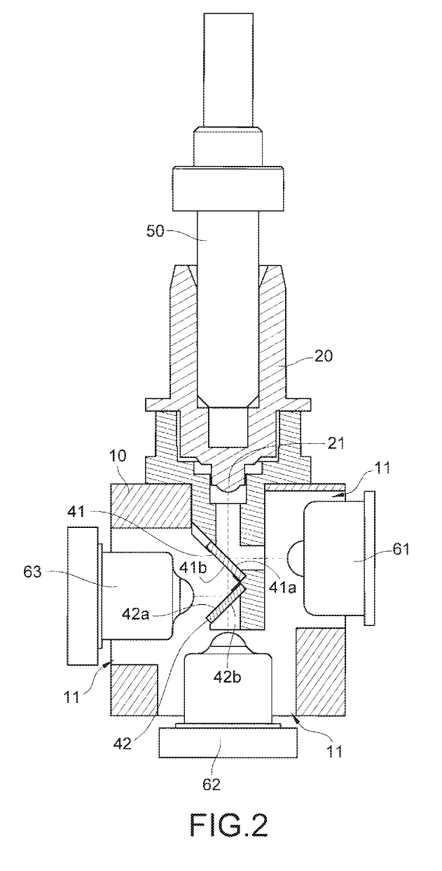

FIG. 2 is a schematic view of a three-way optical device according to a second embodiment of the present invention.

Referring to FIG. 2, in this embodiment, the three-way optical device comprises a case 10, a sleeve 20, an optical receiver 61, an optical receiver 62, an optical receiver 63, and optical filters 41 and 42.

For ease of description, in this embodiment, the number of the optical receivers is three, but the present invention is not limited thereto, and the number of the optical receivers may be one, two, or more than three.

The case 10 has a plurality of openings 11 on surfaces thereof. The plurality of openings 11 may be respectively opened on corresponding surfaces of the case 10.

One end of the sleeve 20 is connected to one of the plurality of openings 11. The sleeve 20 comprises a lens 21. The lens 21 is located on one end of the sleeve 20 connected to the case 10.

The optical receiver 61 is correspondingly disposed in one of the plurality of openings 11.

The optical receiver 62 is correspondingly disposed in one of the plurality of openings 11.

The optical receiver 63 is correspondingly disposed in one of the plurality of openings 11.

The optical filter 41 is located in the case 10 and is disposed corresponding to the optical receiver 61 and the optical receiver 62. The optical receiver 61 corresponds to a first surface 41a of the optical filter 41, and the optical receiver 62 corresponds to a second surface 41b of the optical filter 41.

The optical filter 42 is located in the case 10 and is disposed corresponding to the optical receiver 62 and the optical receiver 63. The optical receiver 63 corresponds to a first surface 42a of the optical filter 42, and the optical receiver 62 corresponds to a second surface 42b of the optical filter 42.

The first surface 41a of the optical filter 41 is obliquely disposed corresponding to the optical receiver 61 and the lens 21, and because of an oblique angle, the optical signal transmitted through the sleeve 20 is reflected to the corresponding optical receiver 61 by the optical filter 41. An incident angle is formed between the optical receiver 61 and one side of a normal line direction of the first surface 41a, and a reflection angle is formed between the lens 21 and the other side of the normal line direction of the first surface 41a, in which the incident angle is equal to or approximates the reflection angle.

The optical filter 41 is correspondingly disposed between the optical receiver 62 and the lens 21, such that the optical signal transmitted through the lens 21 reaches the optical receiver 62 after penetrating the optical filter 41.

The first surface 42a of the optical filter 42 is obliquely disposed corresponding to the optical receiver 63 and the lens 21. Because of an oblique angle, the optical signal penetrating the optical filter 41 is reflected to the corresponding optical receiver 63 by the optical filter 42. An incident angle is formed between the optical receiver 63 and one side of a normal line direction of the first surface 42a, and a reflection angle is formed between the lens 21 and the other side of the normal line direction of the first surface 42a, in which the incident angle is equal to or approximates the reflection angle.

The optical filter 42 is correspondingly disposed between the optical receiver 62 and the lens 21, and the optical filter 42 is correspondingly disposed between the optical filter 41 and the optical receiver 62. Thus, the optical signal transmitted through the lens 21 penetrates the optical filter 41, and then penetrates the optical filter 42, and finally reaches the optical receiver 62.

The optical receiver 61, the optical receiver 62, and the optical receiver 63 are respectively used to receive the optical signals transmitted through the sleeve 20. The optical receiver 61, the optical receiver 62, and the optical receiver 63 are used to receive the optical signals in different bands.

In this embodiment, the three-way optical device further comprises a patch cord 50. One end of the patch cord 50 is inserted into the sleeve 20, and the other end is used to accommodate one end of the optical fiber.

The optical filter 41 selectively enables an optical signal in a first band to penetrate and reflects an optical signal in a second band. In this embodiment, the optical filter 41 is used to selectively enable the optical signal in the first band transmitted through the sleeve 20 to penetrate and reflect the optical signal in the second band transmitted through the sleeve 20, so as to transmit the optical signal in the first band and the optical signal in the second band transmitted through the sleeve 20 to the corresponding optical receiver 61 and optical receiver 62. The optical signal in the first band transmitted through the sleeve 20 is reflected to the optical receiver 61 by the optical filter 41. The optical signal in the second band transmitted through the sleeve 20 reaches the optical receiver 62 after penetrating the optical filter 41. The first band and the second band are within different band ranges.

The optical filter 42 selectively enables the optical signal in the second band to penetrate and reflects an optical signal in a third band. In this embodiment, the optical filter 42 is used to selectively enable the optical signal in the second band transmitted through the sleeve 20 to penetrate or reflect the optical signal in the third band transmitted through the sleeve 20, so as to transmit the optical signal in the second band and the optical signal in the third band transmitted through the sleeve 20 to the corresponding optical receiver 62 and optical receiver 63. The optical signal in the third band transmitted through the sleeve 20 is reflected to the optical receiver 63 by the optical filter 42. The optical signal in the second band transmitted through the sleeve 20 penetrates the optical filter 41, and then penetrates the optical filter 42, and finally reaches the optical receiver 62. The second band and the third band are within different band ranges.

The lens 21 is used to converge the optical signals transmitted through the sleeve 20 and transmit the optical signals to the optical filter 41.

The optical filter 41 and the optical filter 42 are respectively installed within the case 10 by assembling jigs, or may be fixed by the structure of the case 10. Definitely, the optical filter 41 and the optical filter 42 may be fixed within the case 10 in an adhering manner, so as to prevent the optical filter 41 and the optical filter 42 from leaving the optical path when being moved or shaken, thereby avoiding the problems that the optical filter 41 and the optical filter 42 fail to correspond to the optical receiver 61, the optical receiver 62, and the optical receiver 63 and the optical receiver 61, the optical receiver 62, and the optical receiver 63 cannot receive the optical signals transmitted through the sleeve 20.

The patch cord 50 is used to transmit the optical signals transmitted via the optical fiber to the sleeve 20.

The optical receiver 61, the optical receiver 62, and the optical receiver 63 may be p-intrinsic-n (PIN) photodiodes, avalanche photodiodes (APDs), p-intrinsic-n trans-impedance amplifiers (PIN-TIAs), etc.

The optical filter 41 and the optical filter 42 are thin films formed on a transparent substrate in, for example, spreading or coating manner, which allow the optical signals in different bands correspondingly received by the optical receiver 61, the optical receiver 62, and the optical receiver 63 to be reflected and penetrate.

The wavelength of the optical signal received by the optical receiver 61 may be between 800 nm and 900 nm. The wavelength of the optical signal received by the optical receiver 62 may be between 1490 nm and 1610 nm. The wavelength of the optical signal received by the optical receiver 63 may be between 1310 nm and 1350 nm. Definitely, the optical receiver 61, the optical receiver 62, and the optical receiver 63 may receive optical signals in other bands.

The optical filter 41 reflects the incident light having the wavelength between 800 nm and 900 nm, and enables the incident light having the wavelength between 1310 nm and 1610 nm to penetrate, which definitely also enables the incident light in other band ranges to penetrate and to be reflected. The optical filter 42 reflects the incident light having the wavelength between 1250 nm and 1350 nm, and enables the incident light having the wavelength between 1490 nm and 1610 nm to penetrate, which definitely also enables the incident light in other band ranges to penetrate and to be reflected. The above circumstances are merely an embodiment of the present invention, and the present invention is not limited thereto, and the optical filters (41, 42) may select the bands of the incident light to penetrate or to be reflected according to the light emitting elements.

In the three-way optical device according to the present invention, the optical signal transmitted through the sleeve 20 is reflected to the corresponding optical receiver 61 by the optical filter 41, and the optical signal is received by the optical receiver 61. In the three-way optical device, by using the characteristics of the optical filter 41 and the optical filter 42, the optical signal transmitted through the sleeve 20 reaches the optical receiver 62 after sequentially penetrating the optical filter 41 and the optical filter 42, and the optical signal is received by the optical receiver 62. In the three-way optical device, by using the characteristics of the optical filter 41 and the optical filter 42, the optical signal transmitted through the sleeve 20 reaches the optical filter 42 after penetrating the optical filter 41, and then is reflected to the optical receiver 63 by the optical filter 42, and finally the optical signal is received by the optical receiver 63.

In the three-way optical device, the optical filter 41 and the optical filter 42 are used to transmit the optical signals with different wavelengths transmitted to the sleeve 20 via the optical fiber to the corresponding optical receiver 61, optical receiver 62, and optical receiver 63 in selective reflecting and penetrating manners. The three-way optical device achieves the functions of multiplexing and de-multiplexing the optical signals, without resulting in the problem of the loss of signals caused by the grating or optical waveguide used when the optical signals are coupled.

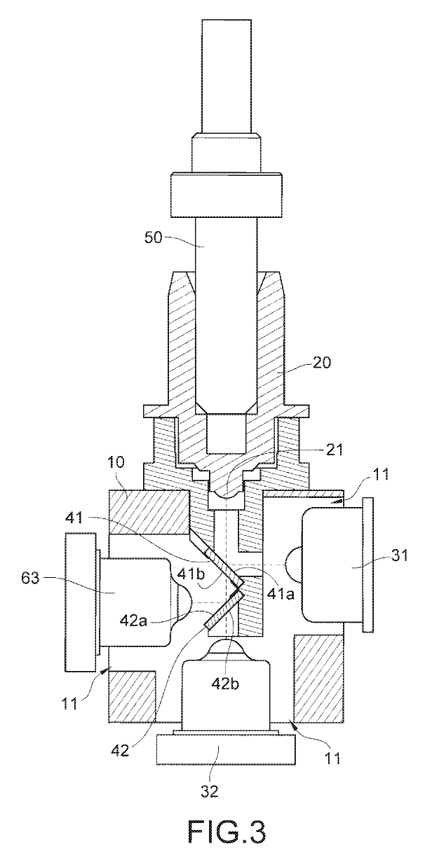

FIG. 3 is a schematic view of a three-way optical device according to a third embodiment of the present invention. The detailed elements can be obtained with reference to the above-mentioned embodiments.

Referring to FIG. 3, in this embodiment, the three-way optical device comprises a case 10, a sleeve 20, an optical transmitter 31, an optical transmitter 32, an optical receiver 63, an optical filter 41, and an optical filter 42.

For ease of description, in this embodiment, the number of the optical transmitters is two, but the present invention is not limited thereto, and the number of the optical transmitters may be one, or more than two.

For ease of description, in this embodiment, the number of the optical receivers is one, but the present invention is not limited thereto, and the number of the optical receivers may be more than one.

The case 10 has a plurality of openings 11 on surfaces thereof. The plurality of openings 11 may be respectively opened on corresponding surfaces of the case 10.

One end of the sleeve 20 is connected to one of the plurality of openings 11. The sleeve 20 comprises a lens 21. The lens 21 is located on one end of the sleeve 20 connected to the case 10.

The optical transmitter 31 is correspondingly disposed in one of the plurality of openings 11.

The optical transmitter 32 is correspondingly disposed in one of the plurality of openings 11.

The optical receiver 63 is correspondingly disposed in one of the plurality of openings 11.

The optical filter 41 is located in the case 10 and is disposed corresponding to the optical transmitter 31 and the optical transmitter 32. The optical transmitter 31 corresponds to a first surface 41a of the optical filter 41, and the optical transmitter 32 corresponds to a second surface 41b of the optical filter 41.

The optical filter 42 is located in the case 10 and is disposed corresponding to the optical transmitter 32 and the optical receiver 63. The optical receiver 63 corresponds to a first surface 42a of the optical filter 42, and the optical transmitter 32 corresponds to a second surface 42b of the optical filter 42.

The first surface 41a of the optical filter 41 is obliquely disposed corresponding to the optical transmitter 31 and the lens 21, and because of an oblique angle, an optical signal sent from the optical transmitter 31 is reflected to the lens 21 by the optical filter 41. An incident angle is formed between the optical transmitter 31 and one side of a normal line direction of the first surface 41a, and a reflection angle is formed between the lens 21 and the other side of the normal line direction of the first surface 41a, in which the incident angle is equal to or approximates the reflection angle.

The optical filter 41 is correspondingly disposed between the optical transmitter 32 and the lens 21, such that an optical signal sent from the optical transmitter 32 reaches the lens 21 after penetrating the optical filter 41.

The first surface 42a of the optical filter 42 is obliquely disposed corresponding to the optical receiver 63 and the lens 21. Because of an oblique angle, the optical signal penetrating the optical filter 41 is reflected to the corresponding optical receiver 63 by the optical filter 42. An incident angle is formed between the optical receiver 63 and one side of a normal line direction of the first surface 42a, and a reflection angle is formed between the lens 21 and the other side of the normal line direction of the first surface 42a, in which the incident angle is equal to or approximates the reflection angle.

The optical filter 42 is correspondingly disposed between the optical transmitter 32 and the lens 21, and the optical filter 42 is correspondingly disposed between the optical filter 41 and the optical transmitter 32. Thus, the optical signal sent from the optical transmitter 32 penetrates the optical filter 42, and then penetrates the optical filter 41, and finally reaches the lens 21.

The optical transmitter 31 and the optical transmitter 32 are respectively used to send the optical signals into the case 10. The wavelengths of the optical signals sent from the optical transmitter 31 and the optical transmitter 32 are in different bands. The optical receiver 63 is used to receive optical signals transmitted through the sleeve 20. The optical receiver 63 is used to receive optical signals having wavelengths in different bands from the wavelengths of the optical signals sent from the optical transmitter 31 and the optical transmitter 32.

In this embodiment, the three-way optical device further comprises a patch cord 50. One end of the patch cord 50 is inserted into the sleeve 20, and the other end is used to accommodate one end of the optical fiber.

The optical filter 41 selectively enables an optical signal in a first band to penetrate and reflects an optical signal in a second band. In this embodiment, the optical filter 41 is used to selectively enable the optical signal in the first band sent from the corresponding optical transmitter 31 to penetrate and reflect the optical signal in the second band sent from the corresponding optical transmitter 32, so as to transmit the optical signal in the first band sent from the corresponding optical transmitter 31 and the optical signal in the second band sent from the corresponding optical transmitter 32 to the sleeve 20. The optical signal in the first band sent from the optical transmitter 31 is reflected to the sleeve 20 by the optical filter 41. The optical signal in the second band sent from the corresponding optical transmitter 32 reaches the sleeve 20 after penetrating the optical filter 41. The first band and the second band are within different band ranges.

The optical filter 42 selectively enables the optical signal in the second band to penetrate and reflects an optical signal in a third band. In this embodiment, the optical filter 42 is used to selectively enable the optical signal in the second band sent from the corresponding optical transmitter 32 to penetrate and selectively reflect the optical signal in the third band transmitted through the sleeve 20, so as to transmit the optical signal in the third band transmitted through the sleeve 20 to the corresponding optical receiver 63. The optical signal in the third band transmitted through the sleeve 20 is reflected to the optical receiver 63 by the optical filter 42. The optical signal in the second band sent from the optical transmitter 32 penetrates the optical filter 42, and then penetrates the optical filter 41, and finally reaches the lens 21. The optical signal in the third band transmitted through the sleeve 20 is reflected to the optical receiver 63 by the optical filter 42. The second band and the third band are within different band ranges.

After the optical signals sent from the optical transmitter 31 and the optical transmitter 32 selectively penetrate and are reflected by the optical filter 41 and the optical filter 42, the lens 21 is used to converge the optical signals into the sleeve 20. The lens 21 is also used to converge and transmit the optical signal transmitted through the sleeve 20 to the optical filter 41.

The optical filter 41 and the optical filter 42 are respectively installed within the case 10 by assembling jigs, or may be fixed by the structure of the case 10. Definitely, the optical filter 41 and the optical filter 42 may be fixed within the case 10 in an adhering manner, so as to prevent the optical filter 41 and the optical filter 42 from leaving the optical path when being moved or shaken, thereby avoiding the problems that the optical filter 41 and the optical filter 42 fail to correspond to the optical transmitter 31, the optical transmitter 32, and the optical receiver 63 and the optical signals sent from the optical transmitter 31 and the optical transmitter 32 cannot be transmitted to the sleeve 20 and the optical receiver 63 cannot receive the optical signal transmitted through the sleeve 20.

After the optical signals are transmitted to the sleeve 20 through being reflected by and penetrating the optical filter 41 and the optical filter 42, the patch cord 50 is used to transmit the optical signals to the optical fiber, and is also used to transmit the optical signals transmitted via the optical fiber to the sleeve 20.

The optical transmitter 31 and the optical transmitter 32 may be LEDs, LDs, or VCSELs, etc.

The optical receiver 63 may be a PIN, an APD, or PIN-TIA, etc.

The optical filter 41 and the optical filter 42 are thin films formed on a transparent substrate in, for example, spreading or coating manner, which allow the optical signals in different bands corresponding to the optical transmitter 31, the optical transmitter 32, and the optical receiver 63 to be reflected and penetrate.

The wavelength of the optical signal sent from the optical transmitter 31 may be between 800 nm and 900 nm. The wavelength of the optical signal sent from the optical transmitter 32 may be between 1490 nm and 1610 nm. The wavelength of the optical signal received by the optical receiver 63 may be between 1310 nm and 1350 nm. The optical transmitter 31, the optical transmitter 32, and the optical receiver 63 may send or receive optical signals in other bands.

The optical filter 41 reflects the incident light having the wavelength between 800 nm and 900 nm, and enables the incident light having the wavelength between 1310 nm and 1610 nm to penetrate. The optical filter 42 reflects the incident light having the wavelength between 1250 nm and 1350 nm, and enables the incident light having the wavelength between 1490 nm and 1610 nm to penetrate. The above circumstances are merely an embodiment of the present invention, and the present invention is not limited thereto, and the optical filters (41, 42) may select the bands of the incident light to penetrate or to be reflected according to the light emitting elements.

In the three-way optical device according to the present invention, the optical signal sent from the corresponding optical transmitter 31 is reflected to the lens 21 by the optical filter 41, then the optical signal is converged into the sleeve 20 by the lens 21, and finally the optical signal is transmitted by the patch cord 50 inserted in the sleeve 20 via the optical fiber connected to the other end of the patch cord 50. In the three-way optical device, by using the characteristics of the optical filter 41 and the optical filter 42, the optical signal sent from the optical transmitter 32 reaches the lens 21 after penetrating the optical filter 41 and the optical filter 42, then the optical signal is converged into the sleeve 20 by the lens 21, and finally the optical signal is transmitted by the patch cord 50 inserted in the sleeve 20 via the optical fiber connected to the other end of the patch cord 50. In the three-way optical device, by using the characteristics of the optical filter 41 and the optical filter 42, the optical signal transmitted through the sleeve 20 reaches the optical filter 42 after penetrating the optical filter 41, then the optical signal is reflected to the optical receiver 63 by the optical filter 42, and finally is received by the optical receiver 63.

In the three-way optical device, the optical filter 41 and the optical filter 42 are used to transmit the optical signals with different wavelengths correspondingly sent from the optical transmitter 31 and the optical transmitter 32 corresponding to different wavelengths to the sleeve 20 in selective reflecting and penetrating manners, and then the optical signals are transmitted via the optical fiber connected to the other end of the sleeve 20. In the three-way optical device, the optical filter 41 and the optical filter 42 are used to transmit the optical signals with different wavelengths transmitted to the sleeve 20 via the optical fiber to the corresponding optical receiver 63 in the selective reflecting and penetrating manners. The three-way optical device achieves the functions of multiplexing and de-multiplexing the optical signals, without resulting in the problem of the loss of signals caused by the grating or optical waveguide used when the optical signals are coupled.

What is claimed is:

1. A three-way optical device, comprising:
a case, having a plurality of openings on surfaces thereof;
a sleeve, having one end connected to one of the plurality of openings;
a plurality of photoelectric elements, each disposed in one of the plurality of openings and associated with an optical signal; and
at least one optical filter, located in the case, wherein each optical filter corresponds to at least two photoelectric elements among the plurality of photoelectric elements and is disposed on an optical path of optical signals associated with the at least two corresponding photoelectric elements, and each optical filter enables the optical signal associated with at least one photoelectric element of the at least two corresponding photoelectric elements to penetrate and reflects the optical signals associated with the remaining photoelectric elements of the at least two corresponding photoelectric elements, and the optical signals reflected by the optical filter and that penetrating the same optical filter have different wavelengths.

2. The three-way optical device according to claim 1, wherein each photoelectric element is one of an optical transmitter and an optical receiver, the optical transmitter is used to send an optical signal into the case, and the optical receiver is used to receive an optical signal transmitted through the sleeve.

3. The three-way optical device according to claim 2, wherein the optical signal sent from the optical transmitter is transmitted to the sleeve via a corresponding optical filter.

4. The three-way optical device according to claim 2, wherein the optical signal transmitted through the sleeve is transmitted to the optical receiver via a corresponding optical filter.

5. The three-way optical device according to claim 1, wherein the sleeve comprises a lens located on one end of the sleeve connected to the case, and the lens is used to converge optical signals.
